(19) United States
(12) Patent Application Publication
(10) Pub. No.: US 2012/0145725 A1
(43) Pub. Date: Jun. 14, 2012

(54) METHOD OF PREPARING CONDUCTIVE RIBS ON A CHASSIS, THE CHASSIS WITH CONDUCTIVE RIBS, AND METHOD OF ASSEMBLING AN ELECTRIC DEVICE INCLUDING THE SAME

(75) Inventors: Chih-Chiang HSU, New Taipei city (TW); Tsung-Ju Chiang, Taoyuan Shien (TW)

(73) Assignee: Quanta Computer Inc., Taoyuan Shien (TW)

(21) Appl. No.: 13/191,693

(22) Filed: Jul. 27, 2011

(30) Foreign Application Priority Data
Dec. 13, 2010 (TW) 099143500

(51) Int. Cl. B65D 90/02; C25D 5/56; C23C 14/34; H05K 13/00

(52) U.S. Cl. 220/669; 29/592.1; 205/164; 205/165; 205/166; 205/167; 204/192.1

(57) ABSTRACT

A method of preparing conductive ribs on a chassis includes steps as follows. A plastic case is provided with at least one elastic rib integrally formed thereon. Then, a conductive film is formed to overlay on both an inner surface of the plastic case and the surfaces of the elastic rib. A chassis with conductive ribs and a method of assembling an electric device including the same are also provided in the invention.

### RELATED APPLICATIONS

This application claims priority to Taiwanese Application Serial Number 099143500, filed Dec. 13, 2010, which is herein incorporated by reference.

### BACKGROUND

1.Technical Field

The present invention relates to a protection component from Electromagnetic Interference (EMI) and Electrostatic discharge (ESD), more particular to a method of preparing conductive ribs on a chassis.

2. Description of Related Art

At present, in order to reduce impacts from Electromagnetic Interference (EMI) and Electrostatic Discharge (ESD) inside a computer, a traditional way is to install a certain quantity of conductive foams, gaskets, Al foils or Cu foils in a chassis of the computer, so as not only to provide with metallic shielding for the computer, but also to conduct the electromagnetic signals to a grounding.

For instance, when the conductive foams are chosen to be installed inside the chassis of the computer, the conductive foam is initially needed to be prepared in which since each conductive foam is made by wrapped a conductive tape on a sponge, thus, before installing the conductive foam in the chassis of the computer, it preliminarily needs to wrap the conductive tape on the sponge.

However, the mentioned steps of wrapping the conductive tape on the sponge and installing the conductive foams inside the chassis need to spend extra labor and manufacturing costs. Moreover, because the conductive foams installed in different positions in the chassis, the conductive foams are different in types, models, prices, and even from different suppliers depends on the positions. Therefore, makers need to weigh the inventory and cost of the conductive foams before preparing and purchasing the conductive foams, such that to further cause much more manpower and cost.

Further, if the conductive tape is defected, the conductive capability of the conductive foam will be degraded, and further to weaken the performance of the computer preventing from Electromagnetic Interference (EMI) and Electrostatic Discharge (ESD).

### SUMMARY

The present invention is to disclose a method of preparing conductive ribs on a chassis and a method of assembling an electric device. By simplifying the manufacturing process, the present invention can decrease manpower and costs for preparing and purchasing the conductive foams mentioned in prior art.

In practice of the present invention, the method of preparing conductive ribs on a chassis comprises steps as follows. First, providing a plastic case wherein the plastic case is provided with an inner surface and at least one elastic rib integrally formed on the inner surface; next, forming a conductive film on the inner surface of the plastic case in which the conductive film is overlaid on both the inner surface of the plastic case and surfaces of the elastic rib.

In additions, in practice of the present invention, the method of assembling an electric device, comprising following steps. First, injecting and forming a plastic case, wherein the plastic case is provided with an inner surface and at least one elastic rib integrally formed on the inner surface of the plastic case; next, depositing to form a conductive film on the inner surface of the plastic case to form a first chassis, wherein the conductive film is overlaid on both the inner surface of the plastic case and surfaces of the elastic rib; next, providing a second chassis and a motherboard, wherein the motherboard is with a component thereon; and assembling the first chassis and the second chassis together, wherein the motherboard is sandwiched between the first chassis and the second chassis, and the elastic rib contacts and presses the component by the conductive film on the elastic rib, and the conductive film is electrically conducted to a grounding of the electric device.

Also, the present invention is further to disclose a chassis with conductive ribs, in which by integrally forming a conductive film on the chassis so as to unify the conductive capability of the conductive film, the present invention can reduce the possibility that a computer is harmed by Electromagnetic Interference (EMI) and Electrostatic Discharge (ESD).

The present invention is to disclose a chassis with conductive ribs in which by integrally forming a conductive film to be overlaid on the chassis, the conductive ribs integrally formed on the chassis can be covered in the conductive film therein so as to enhance the artistic appearance of the chassis.

In one embodiment of the present invention, the chassis with conductive ribs comprises a plastic case and a conductive film. The plastic case comprises an inner surface and at least one elastic rib. The elastic rib has a connection portion and a contacting embossing portion. The connection portion is integrally connected to the inner surface, and the contacting embossing portion is shaped as protruding for contacting and pressing an element. The conductive film is overlaid on both the inner surface of the plastic case and surfaces of the elastic rib for electrically connecting a grounding.

As mentioned above, in the present invention, by forming a conductive film to overlay on both the inner surface of the plastic case and surfaces of the elastic rib, the maker can make decisions not to adopt the prior art of the conductive foams for EMI/ESD shielding so as to simplify the manufacturing process, such as omitting the complicated processes of preparation and purchase of the conductive foams, and to further save manpower and costs.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a flow chart of a method of preparing conductive ribs on a chassis according to one embodiment of the present invention.

FIG. 2(a) to FIG. 2(c) are flow diagrams with a section view of the chassis therein showing the sequential operations according to step (101) to step (102) of FIG. 1 respectively in one variation of the embodiment in FIG. 1.

FIG. 3A is a schematic view of a chassis with conductive ribs according to another embodiment of the present invention.

FIG. 3B is a schematic view of a chassis with conductive ribs in one variation of another embodiment of the present invention.

FIG. 3C is a schematic view of a chassis with conductive ribs in another variation of another embodiment of the present invention.

FIG. 3D is a schematic view of a chassis with conductive ribs in still another variation of another embodiment of the present invention.

FIG. 4 is a flow chart of a method of assembling electric device according to the embodiment of the present invention.

FIG. 5 is a sectional schematic view of the electric device assembled by the method of the present invention.

FIG. 6 is a block diagram of the electric device of the present invention connecting to a grounding.

### DESCRIPTION OF THE PREFERRED EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

In the traditional manufacturing process mentioned above, since the conductive foam needs to be made by wrapping the conductive tape on the sponge before being fixed in the chassis, the present invention substitutes the known conductive foams by directly forming a conductive film to cover both the inner surface of the chassis and an elastic rib of the chassis, so that the present invention simplifies the traditional manufacturing process. Furthermore, the conductive film of the present invention can be not only a shield element, but also can contact and press a component to guide electromagnetic waves generated from the component (or from outside the chassis) to a grounding. The so-called component can be an element with conductive properties, such as connectors, optical disc player etc.

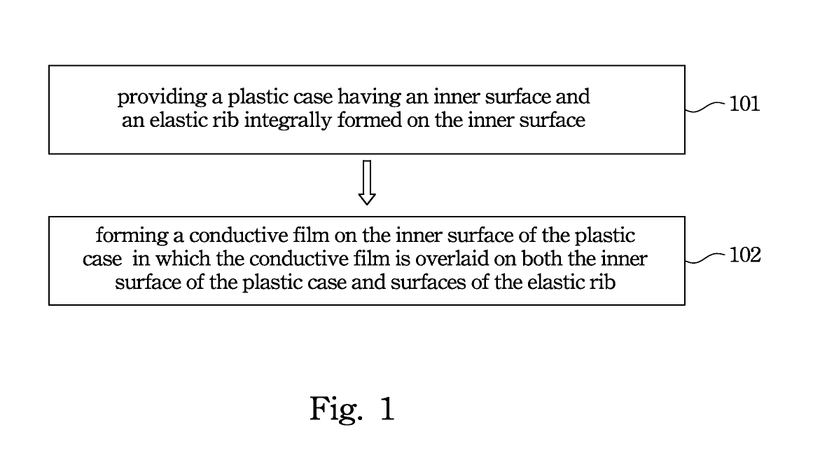

Refer to FIG. 1 in which FIG. 1 is a flow chart of a method of preparing conductive ribs on a chassis according to one embodiment of the present invention.

In practice of the present invention, the method of preparing conductive ribs on a chassis mainly at least comprises steps as following:

Step (101): providing a plastic case in which the plastic case is with an inner surface and at least one elastic rib, and the elastic rib is integrally formed on the inner surface;

Step (102): forming a conductive film on the inner surface of the plastic case in which the conductive film is overlaid on both the inner surface of the plastic case and surfaces of the elastic rib.

Therefore, comparing to the conductive foam of the traditional manufacturing process which needs to be prepared preliminary before being fixed on the chassis, the present invention directly forms the conductive film to cover both the inner surface of the plastic case and the surfaces of the elastic ribs, so as to simplify the traditional manufacturing process.

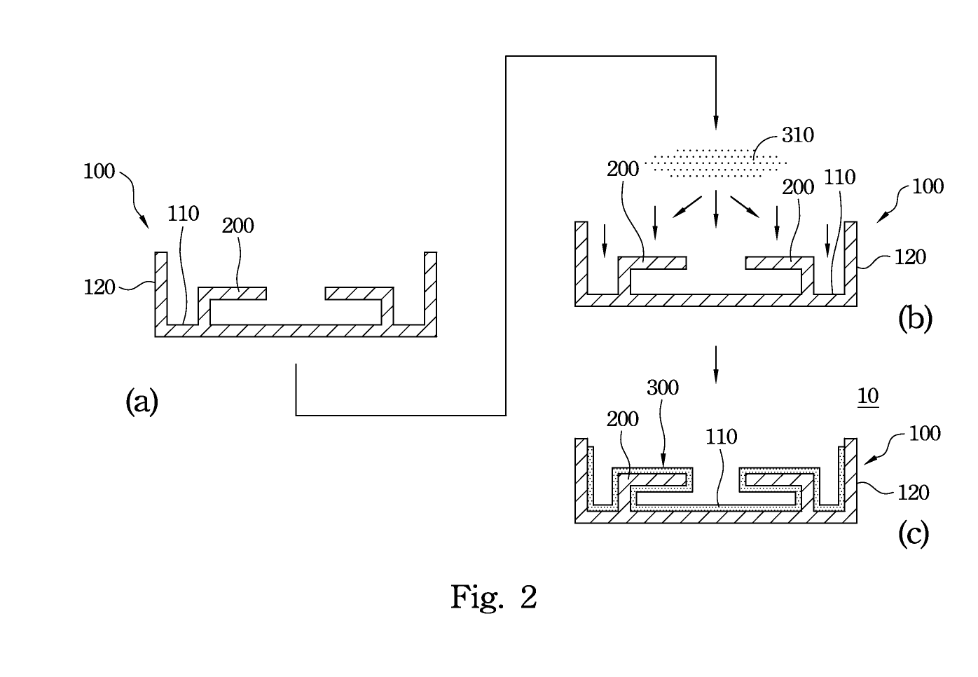

Refer to FIG. FIG. 2(a) to FIG. 2(c) in which FIG. 2(a) to FIG. 2(c) are flow diagrams with a section view of the chassis therein showing the sequential operations according to step (101) to step (102) of FIG. 1 respectively in one variation of the embodiment in FIG. 1.

Refer to FIG. 2(a) first, the embodiment in step (101) is to obtain a plastic case 100 initially. The plastic case 100 has an outer surface 120, an inner surface 110 and a plurality of elastic ribs 200. Yet, the inner surface 110 in this step is not with any metal coating layer.

The plastic case 100, for example, can be made by injection molding, but not limited in the present invention. The elastic ribs 200 and the plastic case 100 are optionally formed together integrally thus the material of the elastic ribs 200 is same as the material of the plastic case 100. Specifically, the elastic ribs 200 are integrally formed on the inner surface 110.

Also, the material of the plastic case 100 is not limited in either, for example, high density polyethylene (HDPE), Polypropylene (PP), Acrylonitrile Butadiene Styrene (ABS), NYLON or the combination thereof.

Refer to FIG. 2(b) and FIG. 2(c) again, in Step (102), specifically, by electroplating means or sputtering deposition means, the embodiment is to proceed by depositing a plurality of metal ions 310 with conductive properties on the inner surface 110 of the plastic case 100 and the surfaces of the elastic ribs 200, thus, the metal ions 310 deposited on the inner surface 110 of the plastic case 100 and the surfaces of the elastic ribs 200 integrally to form a mentioned conductive film 300.

Regarding to the electroplating means, the present invention is not limited into any kinds of electroplating methods, for example, can be one of plastic plating, vacuum plating, composite plating electroless plating, spray plating, immersion plating or plasma plating.

In one of the variations, the electroplating means for example can be vacuum plating. Since the metal ions 310 are deposited on the inner surface 110 of the plastic case 100 and the surfaces of each elastic ribs 200 so as to integrally form the conductive film 300. Thus, after the vacuum plating process is finished, the metal ions 310 are integrally deposited to cover both the inner surface 310 of the plastic case 100 and all surfaces of the elastic ribs 200 (FIG. 2(c)). Therefore, since the metal ions 310 are deposited uniformly, each part of the conductive film 300 is equal in electrical conduction capability.

Otherwise, when the conductive film 300 is formed by sputtering deposition means, the sputtering deposition means for example, can be a method of vacuum plating.

While depositing by either the electroplating means or the sputtering deposition means, the conductive film 300 in the invention is not limited in material, for example, can be adopted to be made of aluminum, nickel, copper, chromium, tin, titanium, stainless steel and the combination thereof.

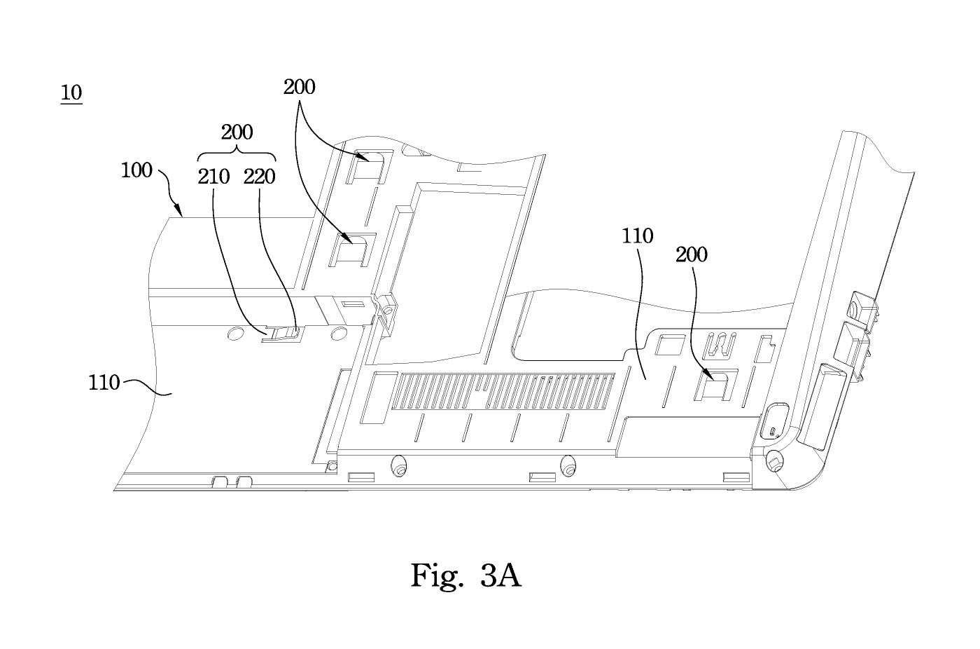

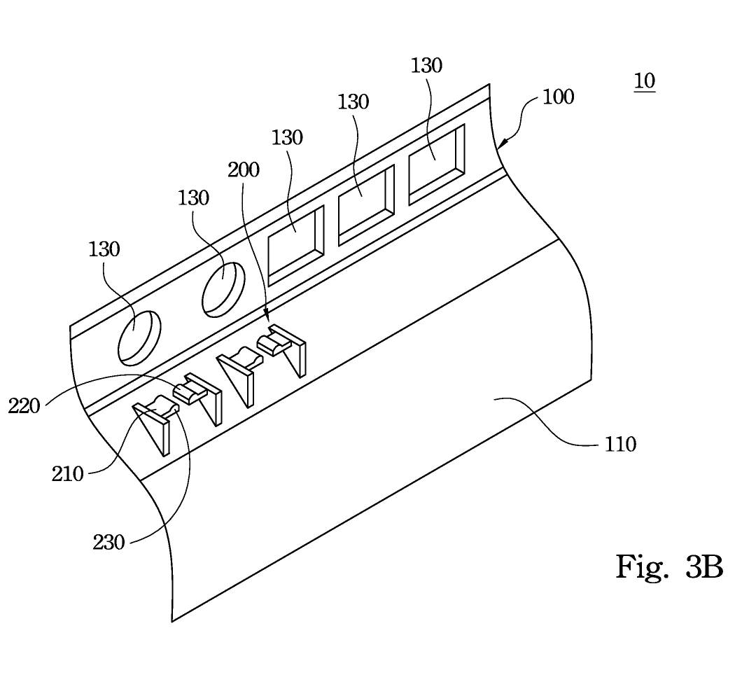

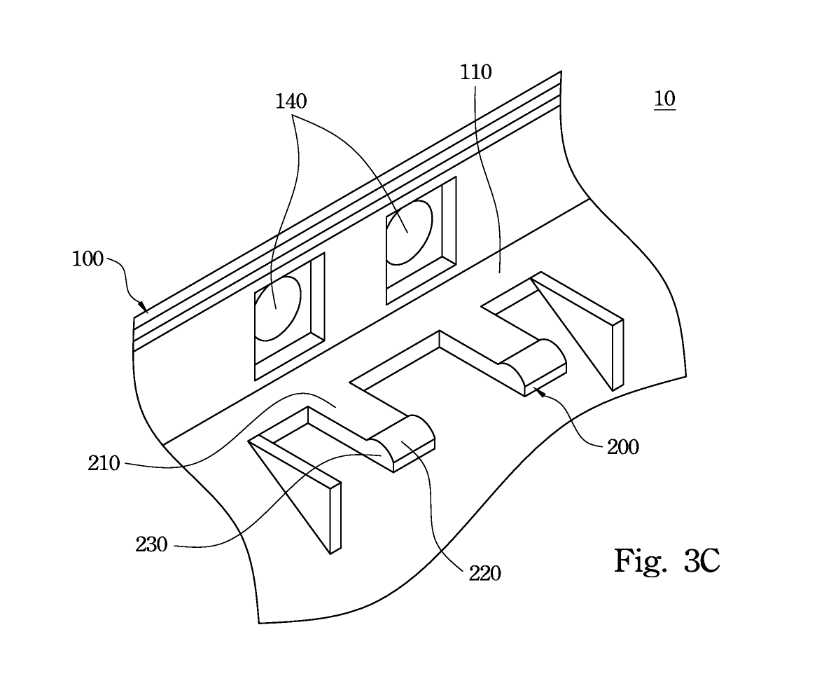

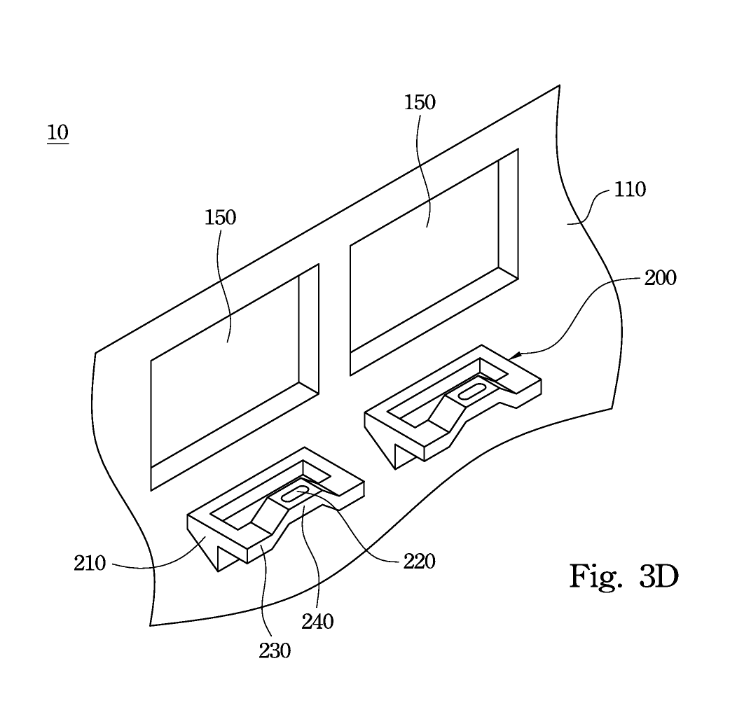

Refer to FIG. 3A and FIG. 2(c) in which FIG. 3A is a schematic view of a chassis with conductive ribs according to another embodiment of the present invention. Since the conductive film has been overlaid on both the inner surface of the plastic case and the surfaces of the elastic ribs, however, in order to conveniently illustrate the plastic case 100 and elastic ribs 200, the conductive film is not indicated with reference numbers.

A chassis 10 made by the described Step (101) and Step (102) comprises a plastic case 100, a plurality of elastic ribs 200 and a conductive film 300 (See FIG. 2(c)).

Each elastic rib 200 is not limited in shape (see following paragraphs) and location on the inner surface 110, as long as the conductive film 300 overlaid on the elastic rib 200 contacts and presses one component (e.g. card reader or connector) in the chassis 10.

In one embodiment of the present invention, refer to FIG. 3A again, the elastic rib 200 is provided with at least one connection portion 210 and a contacting embossing portion 220. The connection portion 210 is located on one end of the elastic rib 200, and is integrally connected to the inner surface 110 of the plastic case 100. The contacting embossing portion 220 is not limited to be located on one end of the elastic rib 200 being far away from the connection portion 210, or on a section between two opposite ends of the elastic rib 200. The contacting embossing portion 220 is preferably to be shaped as protruding, thus, when the contacting embossing portion 220 contacts and presses a component, the elastic rib 200 will be deformed, and elasticity generated from the deformed elastic rib 200 will continually urge the contacting embossing portion 220 to press the component.

Refer to FIG. 3B in which FIG. 3B is a schematic view of a chassis with conductive ribs in one variation of another embodiment of the present invention. The conductive film is not indicated with reference numbers.

One side of the plastic case 100 can be configured with a plurality of first recesses 130, and these first recesses 130 can be connector of interfaces such as USB, 1394, D-sub. The connection portion 210 of the conductive rib 200 is integrally formed and connected with the inner surface 110 of the plastic case 100 neighboring to the first recesses 130. One end of the elastic rib 200 far away from the end where the connection portion 210 located is a free end 230 which does not connect to the inner surface 110 of the plastic case 100, and the contacting embossing portion 220 is located on the free end 230. The Free ends 230 of two neighboring elastic ribs 200 are facing with each other.

Refer to FIG. 3C in which FIG. 3C is a schematic view of a chassis 10 with conductive ribs 200 in another variation of another embodiment of the present invention.

Another side of the plastic case 100 can be configured with a plurality of second recesses 140. The connection portion 210 of the conductive rib 200 is integrally formed on the inner surface 110 of the plastic case 100 neighboring to the second recesses 140, and the connection portion 210 of the conductive rib 200 is extended away from the second recesses 140. One end of the elastic rib 200 far away from the end where connection portion 210 located is a free end 230 which does not connect to the inner surface 110 of the plastic case 100, and the contacting embossing portion 220 is located on the free end 230.

Refer to FIG. 3D in which FIG. 3D is a schematic view of a chassis with conductive ribs in still another variation of another embodiment of the present invention. Another side of the plastic case 100 can be configured with a plurality of third recesses 150. The connection portion 210 of the conductive rib 200 is integrally connected to the inner surface 110 of the plastic case 100 neighboring to the third recesses 150, and the connection portion 210 of the conductive rib 200 is extended away from the third recesses 150.

One end of the elastic rib 200 far away from the end where the connection portion 210 located is a free end 230 which does not connect to the inner surface 110 of the plastic case 100, and the contacting embossing portion 220 is located on one protruding arc 240 of the free end 230.

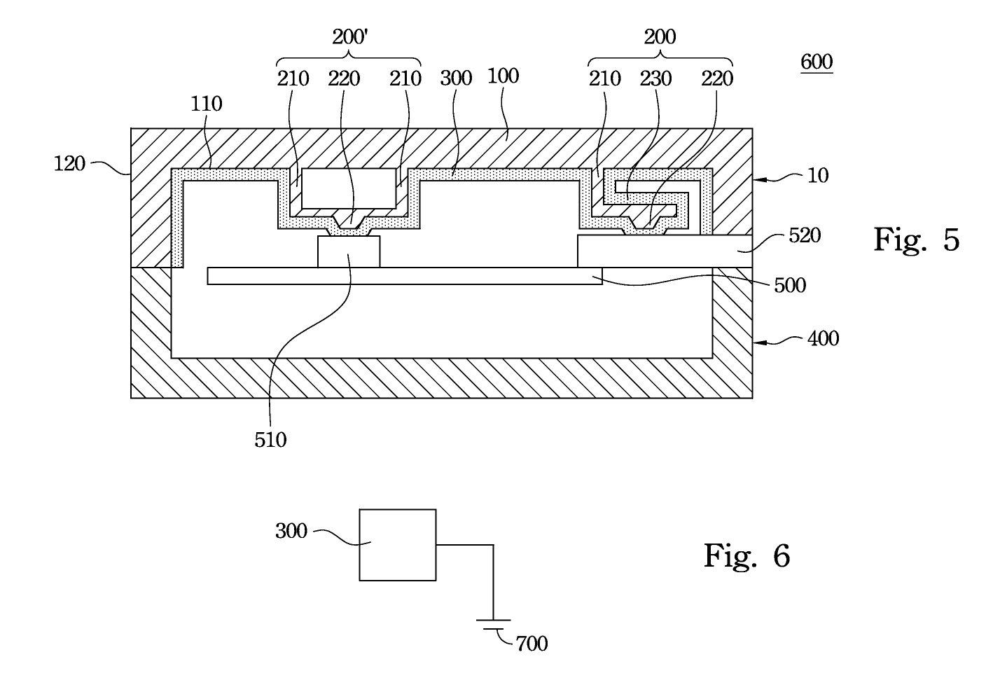

Refer to FIG. 5 in which FIG. 5 is a sectional schematic view of the electric device assembled by the method of the present invention. In another variation of the embodiment, one end of the elastic rib 200′ far away from the end where the connection portion 210 located is another connection portion 210 integrally connected to the inner surface 110 of the plastic case 100, and the contacting embossing portion 220 is located between the connection portions 210 of the elastic rib 200′.

In another embodiment of the invention, the chassis 10 with conductive ribs can be implemented on one electric device such as notebook, mobile phone, GPS etc.

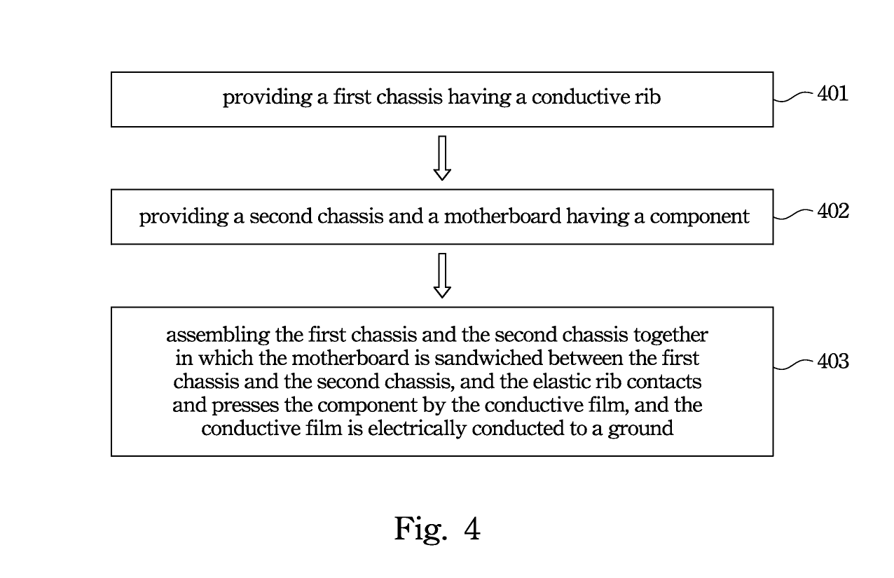

Refer to FIG. 4-6 in which FIG. 4 is a flow chart of a method of assembling electric device 600 according to the embodiment of the present invention, and FIG. 6 is a block diagram of the electric device 600 of the present invention connecting to a grounding 700.

The assembling method of electric device 600 includes steps as follows:

Step (401): providing a first chassis 10 mentioned above (FIG. 2(c)).

Step (402): providing at least a second chassis 400 and at least a motherboard 500. The second chassis 400 is not limited to be the same with the first chassis 10 having the elastic rib 200 and conductive film 300 as well. The motherboard 500 can be provided with a component 510 (e.g. processing chip) thereon and at least an I/O interface 520 (e.g. card reader or connector). The component 510 is configured inside the first chassis 10; the I/O interface 520 can be located between the first chassis 10 and the second chassis 400, or the I/O interface 520 can be located on a lateral side of the first chassis 10 but not connect to the second chassis 400, or the I/O interface 520 can be located on a lateral side of the second chassis 400 but not connect to the first chassis 10. Also, the I/O interface 520 is electrically connected to the mother board 500, and served for connect to a external device such as USB type external device, flash drive or memory card etc,

Step (403): assembling the first chassis 10 and the second chassis 400 together. The motherboard 500 is sandwiched between the first chassis 10 and the second chassis 400, and the contacting embossing portion 220 of the elastic rib 200′ contacts and presses a grounding (e.g. metal shell) of the component 510 by a section of the conductive film 300 overlaid on the contacting embossing portion 220 so as to ensure the conductive film 300 and the negative of the component 510 can be electrically conducted with each other appropriately (FIG. 5 of left elastic rib 200′). Furthermore, the contacting embossing portion 220 of the elastic rib 200 contacts and presses a grounding (e.g. metal shell) of the I/O interface 520 by another section of the conductive film 300 overlaid on the contacting embossing portion 220 so as to ensure the conductive film 300 and the negative of the I/O interface 520 can be electrically conducted with each other appropriately (FIG. 5 of right elastic rib 200). Also, the conductive film 300 is electrically conducted to a grounding 700 (FIG. 6); the grounding 700 is not limited to the grounding of the motherboard 500 only, anyone having ordinary skills in the art of the present invention will be familiar to electrically connect the conductive film 300 with the grounding 700, the grounding 700 will not be discussed in details.

Thus, no matter the electromagnetic waves are generated from inside or outside of the electric device 600, by being contacted and pressed by the conductive film 300 overlaid on the contacting embossing portion 220 of the elastic rib 200, the electromagnetic waves can be guided to the grounding 700 via the conductive film 300 so as to easily eliminate noise signals or static signals.

Also, since the conductive film 300 is formed integrally, each area of the conductive film 300 is equal in electrical conduction capability, so as to reduce the possibility that the electric device 600 is harmed by EMI/ESD.

The invention eliminates the conventional solution that adopts the conductive foams, gaskets, Al foils or Cu foils to guide the electromagnetic waves away so as to help decrease manpower and costs for preparing and purchasing the conductive foams, gaskets, Al foils or Cu foils mentioned in prior art.

Moreover, needed to know again, the attached drawings are only for illustration, the distribution of the elastic ribs 200 can be varied depending on different model Numbers or types, not has to be arranged as shown in FIG. 5 only.

What needed to be considered is that, in Step (102) of FIG. 1, the conductive film 300 is not completely overlaid exactly on the inner surface 110 of the plastic case 100, and in Step (403) of FIG. 4, in principle, the section of the conductive film 300 overlaid on the contacting embossing portion 220 will be considered not contacting any “non-grounding ” terminals (e.g. Vcc pin) of the component 510.

Finally, the terms “inner surface 110” and “outer surface 120” in the specification mentioned above are needed to be distinguished wherein the surfaces of the plastic case 100 which could be exposed outwards the plastic case 100 are called “outer surface 120”, otherwise, other surfaces of the first chassis 10 which could be hided inside the first chassis 10 are called “inner surface 110” when the first chassis 10 is assembled with other chassis together. For instance, the so-called “inner surface 110” might be a surface of the plastic case 100 opposite to the outer surface 120, or a surface of a rib of the plastic case 100 extended towards a direction opposite to the outer surface 120, or even, a surface of a flange extended towards a direction of the outer surface 120 etc.

Although the present invention has been described with reference to the preferred embodiments thereof, it is apparent to those skilled in the art that a variety of modifications and changes may be made without departing from the scope of the present invention which is intended to be defined by the appended claims.

The readers attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A method of preparing conductive ribs on a chassis, the method comprising:
providing a plastic case wherein the plastic case is provided with an inner surface and at least one elastic rib integrally formed on the inner surface; and
forming a conductive film overlaid on both the inner surface of the plastic case and surfaces of the elastic rib.

2. The method of preparing conductive ribs on a chassis according to claim 1, wherein forming the conductive film on the inner surface of the plastic case comprises:
by electroplating means, depositing a plurality of metal ions with conductive properties on both the inner surface of the plastic case and the surfaces of the elastic rib to form the conductive film integrally.

3. The method of preparing conductive ribs on a chassis according to claim 2, wherein the electroplating means is a method of plastic plating, vacuum plating, composite plating- electroless plating, spray plating, immersion plating or plasma plating.

4. The method of preparing conductive ribs on a chassis according to claim 1, wherein the material of the conductive film is selected from the group consisting of aluminum, nickel, copper, chromium, tin, titanium, stainless steel and the combination thereof.

5. The method of preparing conductive ribs on a chassis according to claim 1, wherein forming the conductive film on the inner surface of the plastic case comprises:
by sputtering deposition means, depositing a plurality of metal ions with conductive properties on both the inner surface of the plastic case and the surfaces of the elastic rib to form the conductive film integrally.

6. The method of preparing conductive ribs on a chassis according to claim 5, wherein the sputtering deposition means is a method of vacuum plating.

7. A chassis with conductive ribs, comprising:
a plastic case comprising:
an inner surface; and
at least one elastic rib having a connection portion and a contacting embossing portion, wherein the connection portion is integrally connected to the inner surface, and the contacting embossing portion is shaped as protruding for contacting and pressing an element; and
a conductive film overlaid on both the inner surface of the plastic case and surfaces of the elastic rib, for electrically connecting a grounding.

8. The chassis with conductive ribs according to claim 7, wherein one end of the elastic rib being far away from the connection portion is a free end, and the contacting embossing portion is located on the free end.

9. The chassis with conductive ribs according to claim 7, wherein one end of the elastic rib being far away from the connection portion is another connection portion integrally connected to the inner surface of the plastic case, and the contacting embossing portion is located between the connection portions of the elastic rib.

10. The chassis with conductive ribs according to claim 7, wherein the material of the conductive film is selected from the group consisting of aluminum, nickel, copper, chromium, tin, titanium, stainless steel and the combination thereof.

11. A method of assembling an electric device, comprising:
injecting and forming a plastic case, wherein the plastic case is provided with an inner surface and at least one elastic rib integrally formed on the inner surface of the plastic case;
depositing a conductive film to form a first chassis, wherein the conductive film is overlaid on both the inner surface of the plastic case and surfaces of the elastic rib;
providing a second chassis and a motherboard, wherein the motherboard is with a component thereon; and
assembling the first chassis and the second chassis together, wherein the motherboard is sandwiched between the first chassis and the second chassis, and the elastic rib contacts and presses the component by the conductive film on the elastic rib, and the conductive film is electrically conducted to a grounding of the electric device.

12. The method of assembling an electric device according to claim 11, wherein the elastic rib is provided with a connection portion and a contacting embossing portion, wherein the connection portion is integrally connected to the inner surface of the first chassis, and the contacting embossing portion is shaped as protruding.

13. The method of assembling an electric device according to claim 12, wherein the contacting embossing portion of the elastic rib contacts and presses the component.

14. The method of assembling an electric device according to claim 12, wherein one end of the elastic rib being far away from the connection portion is a free end, and the contacting embossing portion is located on the free end.

15. The method of assembling an electric device according to claim 12, wherein one end of the elastic rib being far away from the connection portion is another connection portion integrally connected to the inner surface of the plastic case, and the contacting embossing portion is located between the connection portions of the elastic rib.
